(19) United States
(12) Patent Application Publication
(10) Pub. No.: US 2013/0168867 A1
(43) Pub. Date: Jul. 4, 2013

(54) METHOD FOR FORMING METAL LINE IN SEMICONDUCTOR DEVICE

(71) Applicant: Sang Chul SHIM, Seoul (KR)

(72) Inventor: Sang Chul SHIM, Seoul (KR)

(73) Assignee: Dongbu HiTek Co., Ltd., Seoul (KR)

(21) Appl. No.: 13/438,648

(22) Filed: Apr. 3, 2012

(30) Foreign Application Priority Data
Dec. 29, 2011 (KR) 10-2011-0146421

(51) Int. Cl. H01L 23/528; H01L 21/768

(52) U.S. Cl. 257/773; 438/626; 257/E21.577; 257/E23.151

(57) ABSTRACT

A method for forming a metal line in a semiconductor device and an associated apparatus. The method includes at least one of (1) Depositing a metal line layer and a metal contact layer over a semiconductor substrate. (2) Patterning the metal contact layer and the metal line layer to form a primarily formed contact portion and a lower metal line. (3) Patterning the primarily formed contact portion to form a secondarily formed contact portion. (4) Forming an insulating film on the semiconductor substrate including the secondarily formed contact portion and the lower metal line. (5) Planarizing the insulating film such that the secondarily formed contact portion is exposed. (6) Forming an upper metal line over the planarized insulating film to be in electrical contact with the secondarily formed contact portion.

The present application claims priority under 35 U.S.C. §119 to Korean Patent Application No. 10-2011-0146421 (filed on Dec. 29, 2011), which is hereby incorporated by reference in its entirety.

### BACKGROUND

FIGS. 1A to 1D are cross-sectional views illustrating a method for forming a metal line in a semiconductor device, in accordance with the related art. As illustrated in FIG. 1A, insulating film 20 may be formed on/over semiconductor substrate 10. A photo-resist pattern for defining a contact formation area may be formed on/over insulating film 20. Contact hole 60 may be formed in the contact formation area of insulating film 20 by a patterning process using a photo-resist pattern.

As illustrated in FIG. 1B, multiple barrier metal layers 30 and 40 may be formed inside contact hole 60 and on/over insulating film 20. Metal may be filled in to contact hole 60 with barrier metal layers 30 and 40 to form contact metal layer 50. As illustrated in FIG. 1C, semiconductor substrate 10 with contact metal layer 50 may be planarized until insulating film 20 is exposed by chemical mechanical polishing (CMP) (or similar process), thereby forming a contact. As illustrated in FIG. 1D, glue layer 70, metal line layer 80, and/or anti-reflective coating layer 90 may be sequentially deposited and patterned to form a metal line.

In a related art method of forming a metal line, with reference to examples illustrated in FIGS. 1A to 1D, a contact is formed by the process of forming a contact hole, forming barrier metal layers inside the contact hole, and filing in metal inside the contact hole. Because related art semiconductors may be highly integrated with relatively high aspect ratios, breakage of the barrier metal layers may occur because of poor step coverage when the barrier metal layers are formed inside the contact hole.

The relatively high aspect ratio of related art semiconductor devices, creates difficulties in filling aluminum in a contact hole by sputtering methods when a contact metal layer is buried in the contact hole. In the related art, to avoid breakage of the barrier metal layers, tungsten may be filled in the contact hole by chemical vapor deposition (CVD) to use the tungsten as a plug. However, tungsten has a higher resistivity than aluminum, which may lead to higher contact resistance. In the related art, electro-migration (EM) characteristics may be deteriorated or degraded at a joined region of the contact and the contact metal layer (i.e. an interface between the aluminum and the tungsten plug). Also, in the related art, the use of borderless vias may have the limitation of a high probability of defects caused by misalignment when a metal line is formed on top of the contact.

### SUMMARY

Embodiments relate to a method of forming a metal line in a semiconductor device, in which the metal line is formed by depositing and patterning a metal layer without forming and burying a contact hole.

Embodiments relate to a method of forming a metal line in a semiconductor device by stacking and patterning a metal layer without forming and burying a contact hole. Embodiments may simplify the formation of a metal line because the process of forming a barrier metal layer inside a contact hole is eliminated. Accordingly, embodiments may eliminate, reduce, and/or mitigate various types of problems that may occur when the barrier metal layer is formed inside the contact hole.

In accordance with embodiments, a method of forming a metal line in a semiconductor device includes at least one of the following: (1) Depositing a metal line layer and a metal contact layer on/over a semiconductor substrate. (2) Patterning the metal contact layer and the metal line layer to form a primarily formed contact portion and a lower metal line. (3) Patterning the primarily formed contact portion to form a secondarily formed contact portion. (4) Forming an insulating film on/over the semiconductor substrate including the secondarily formed contact portion and the lower metal line. (5) Planarizing the insulating film such that the secondarily formed contact portion is exposed. (6) Forming an upper metal line on/over the planarized insulating film so as to be in contact with the secondarily formed contact portion.

In embodiments, the secondarily formed contact portion has a polygonal or circular cross-section. In embodiments, before patterning the formed contact portion to form a secondarily formed contact portion, a passivation film is formed to cover a sidewall of the lower metal line. In embodiments, an anti-reflective coating layer is formed on either an interface between the metal line layer and the metal contact layer, the top surface of the metal contact layer, and/or the top surface of the upper metal line. In embodiments, a barrier metal film is formed on/over an interface between the semiconductor substrate and the metal line layer. In embodiments, the metal line layer, the metal contact layer, and the upper metal line are formed of aluminum.

### BRIEF DESCRIPTION OF THE DRAWINGS

The above and other objects and features of embodiments will become apparent from the following description of embodiments, given in conjunction with the accompanying drawings, in which:

FIGS. 1A to 1D are cross-sectional views illustrating a method for forming a metal line in a semiconductor device, in accordance with the related art.

FIGS. 2A to 2L are cross-sectional views illustrating a method of forming a metal line in a semiconductor device, in accordance with embodiments.

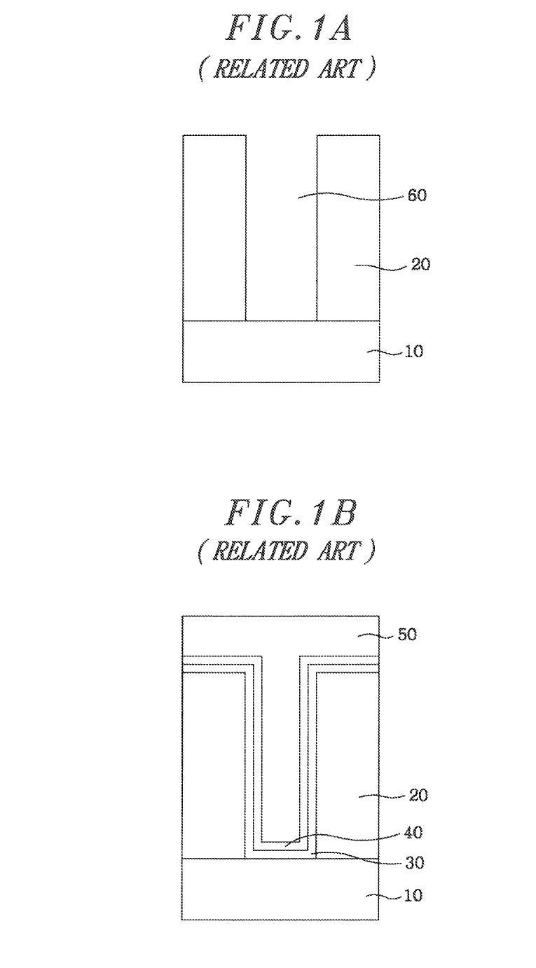

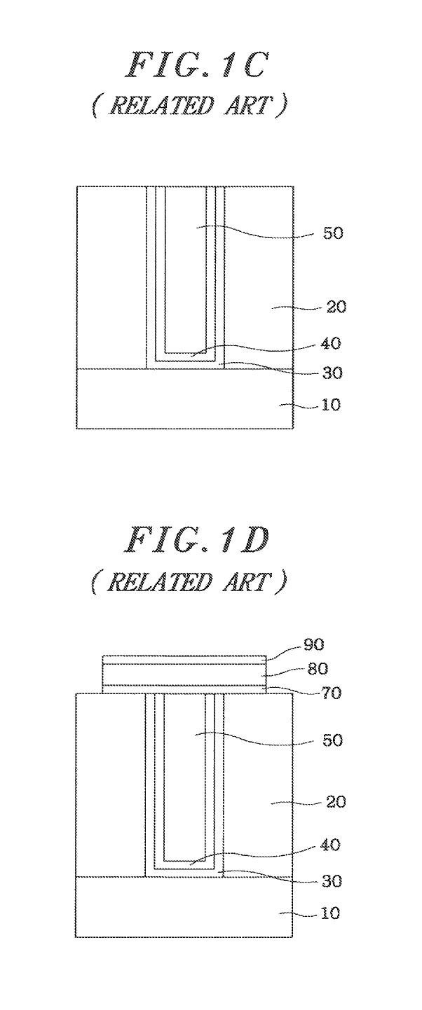

### DETAILED DESCRIPTION

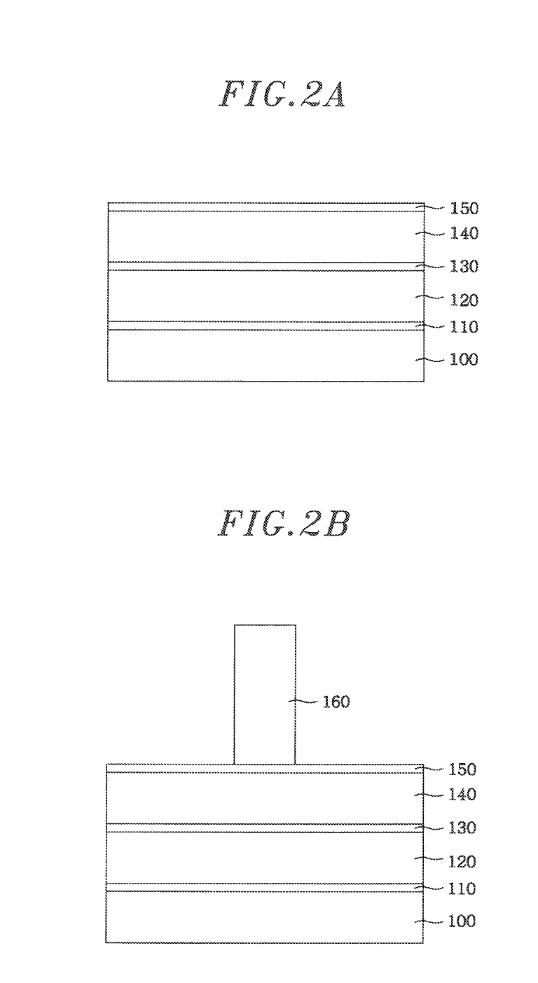

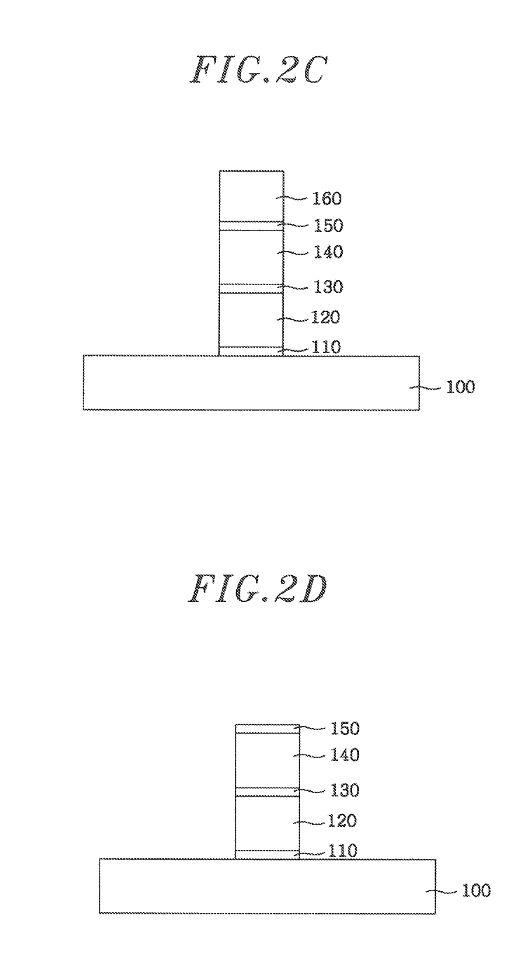

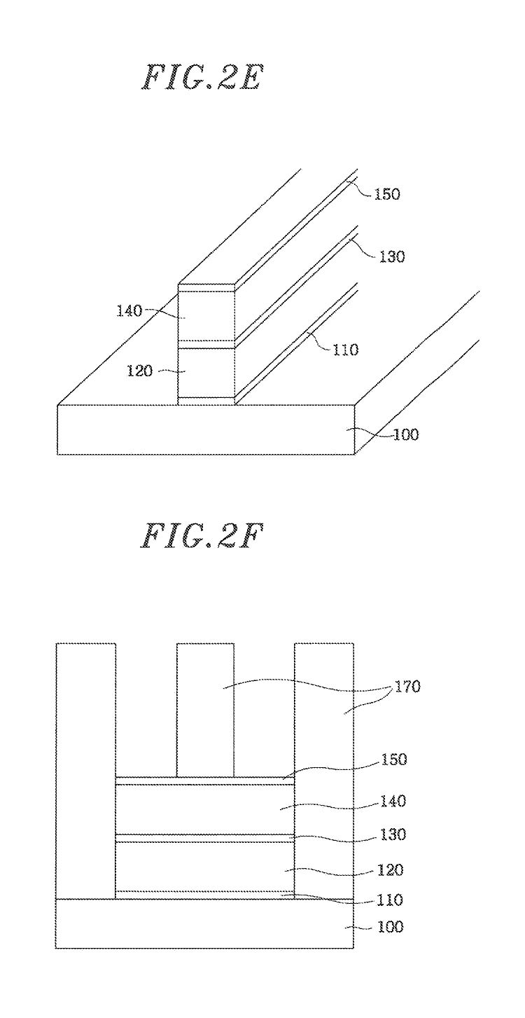

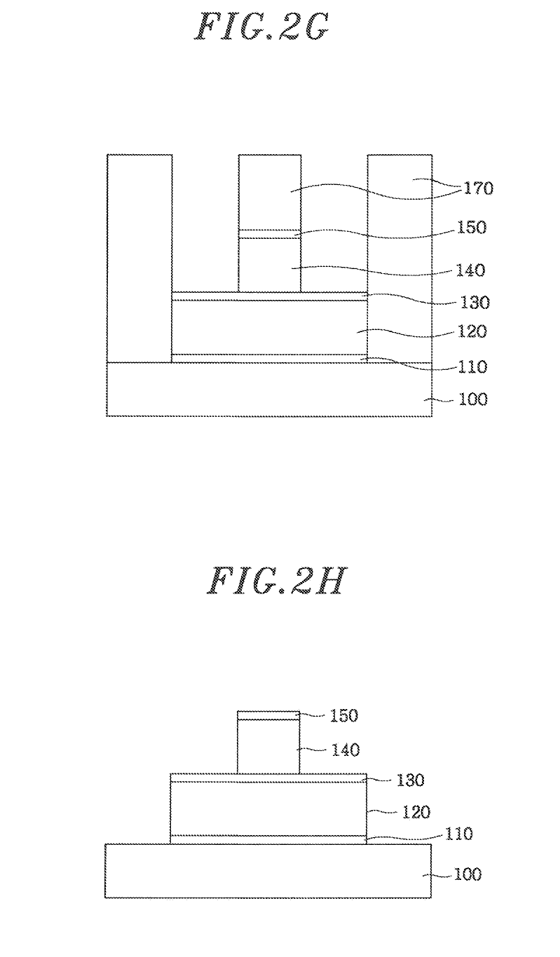

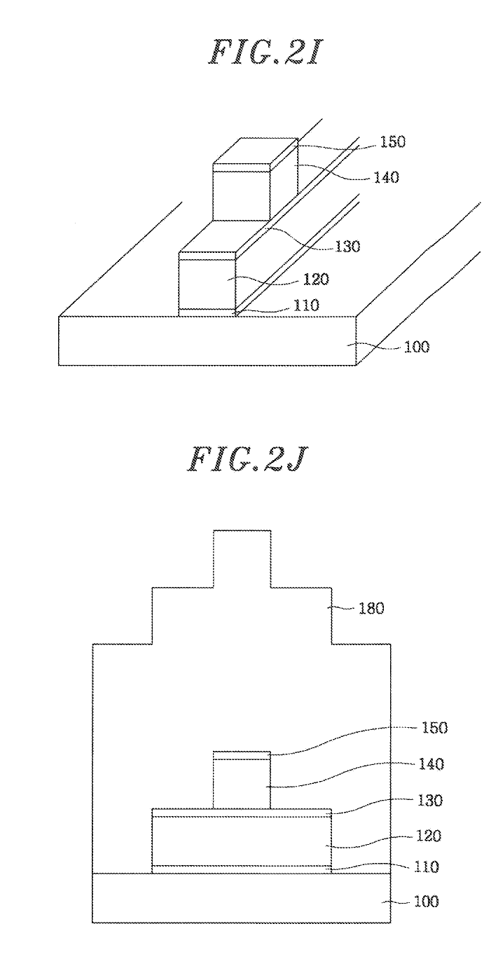

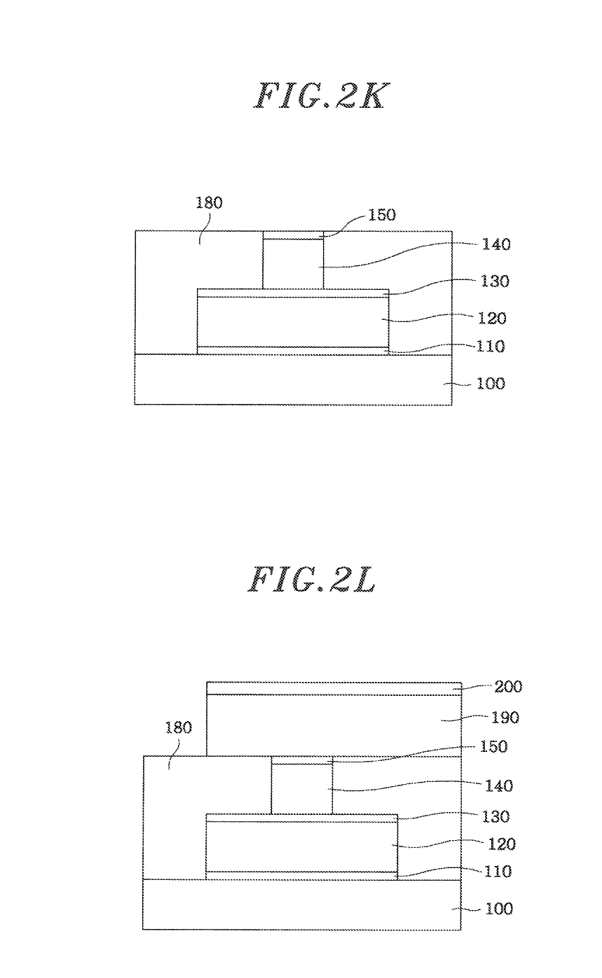

FIGS. 2A to 2L are cross-sectional views illustrating a method of forming a metal line of a semiconductor device, in accordance with embodiments. FIG. 2L illustrates a semiconductor device structure resulting from the method illustrated in FIGS. 2A-2K for forming a metal line, in accordance with embodiments.

In a semiconductor device according to embodiments, barrier metal layer 110 may be deposited on/over semiconductor substrate 100. Lower metal line layer 120 may be deposited and patterned on/over barrier metal layer 110, in accordance with embodiments. For example, in embodiments, barrier metal layer 110 may be made of a single film of titanium (Ti), titanium nitride (TiN), a compound of titanium and tungsten (TiW), tantalum (Ta), tantalum nitride (TaN), or a single film including any combination of these materials. In embodiments, lower metal line layer 120 may be formed of aluminum.

First anti-reflective coating layer 130 may be deposited on/over lower metal line layer 120. A metal contact layer 140 may be deposited and patterned on/over first anti-reflective coating layer 130 and may be used as a contact portion. Second anti-reflective coating layer 150 may be deposited on/over metal contact layer 140. In embodiments, one or both of first anti-reflective coating layer 130 and second anti-reflective coating layer 150 may be made of a single film of titanium (Ti), titanium nitride (TiN), a compound of titanium and tungsten (TiW), tantalum (Ta), tantalum nitride (TaN), or a single film made of a combination of materials. In embodiments, metal contact layer 140 may be formed of aluminum.

In embodiments, lower metal line layer 120, first anti-reflective coating layer 130, and metal contact layer 140 may be isolated and protected from the surroundings by being enclosed by insulating film 180. In embodiments, insulating film 180 may be made of an oxide film such as a silicon oxide film (SiO₂).

In embodiments, upper metal line layer 190 may be patterned on/over the insulating film 180 and used as upper wiring. Upper metal line layer 190 may be deposited to be electrically connected to metal contact layer 140 via second anti-reflective coating layer 150. Third anti-reflective coating layer 200 may be deposited on/over upper metal line layer 190. In embodiments, upper metal line layer 190 may be formed of aluminum. In embodiments, third anti-reflective coating layer 200 may be formed as a single film using a film made of titanium (Ti), titanium nitride (TiN), a compound of titanium and tungsten (TiW), tantalum (Ta), tantalum nitride (TaN), or as a single film using a film made of a combination of these materials. In embodiments, third anti-reflective coating layer 200 may be formed as a combined film using multiple films.

In accordance with embodiments, barrier metal layer 110, first anti-reflective coating layer 130, second anti-reflective coating layer 150, third anti-reflective coating layer 200, and/or may be selectively omitted depending on embodiments.

A method of forming a metal line in accordance with embodiments is illustrated in example FIGS. 2A to 2L. As illustrated in FIG. 2A, lower metal line layer 120 and metal contact layer 140 are deposited on/over semiconductor substrate 100, in accordance with embodiments. In embodiments, barrier metal layer 110 may be formed on/over an interface between semiconductor substrate 100 and lower metal line layer 120. In embodiments, first anti-reflective coating layer 130 may be formed on/over an interface between lower metal line layer 120 and metal contact layer 140. In embodiments, second anti-reflective coating layer 150 may be formed on/over the top surface of metal contact layer 140. Lower metal line layer 120, first anti-reflective coating layer 130, metal contact layer 140, and/or second anti-reflective coating layer 150 may be formed in-situ.

For example, in embodiments, lower metal line layer 120 and metal contact layer 140 may be formed of aluminum. Barrier metal layers 110, first anti-reflective coating layer 130, and/or second anti-reflective coating layer 150 may be formed of a single film titanium (Ti), titanium nitride (TiN), a compound of titanium and tungsten (TiW), tantalum (Ta), tantalum nitride (TaN), or a single film that is a combination of these materials. In embodiments, a single film or a combined film may be deposited and formed by a sputtering method, a CVD method, and/or a similar method.

As illustrated in FIG. 2B, first pattern film 160 may be formed on top of the second anti-reflective coating layer 150 and may define the shape of metal contact layer 140 and second anti-reflective coating layer 150, in accordance with embodiments. In embodiments, first pattern film 160 may be formed using a photo-resist.

As illustrated in FIG. 2C, first pattern film 160 may be used to pattern second anti-reflective coating layer 150, metal contact layer 140, first anti-reflective coating layer 130, lower metal line layer 120, and/or barrier metal layer 110, in accordance with embodiments. In embodiments, a lower metal line may be formed using lower metal line layer 120. During this process, in embodiments, metal contact layer 140 may be patterned in the shape of a metal line, thereby primarily forming a contact portion connecting the lower metal line and the upper metal line (to be formed subsequently).

As illustrated in FIG. 2D, first pattern film 160 may be removed, in accordance with embodiments.

FIG. 2E is a three dimensional depiction of the structure illustrated in FIG. 2D, in accordance with embodiments. FIG. 2F illustrates the structure shown in FIG. 2D, when viewed orthogonally in a lengthwise direction of the lower metal line formed by lower metal line layer 120, in accordance with embodiments.

As illustrated in FIG. 2F, second pattern film 170 may be formed on top of second anti-reflective coating layer 150 and may define the shape of the contact portion, in accordance with embodiments. In embodiments, second pattern film 170 may be formed using a photo-resist. In embodiments, second pattern film 170 may be formed in such a shape as to cover a sidewall of the lower metal line formed by lower metal line layer 120.

As illustrated in FIG. 2G, second pattern film 170 may be used to pattern second anti-reflective coating layer 150 and metal contact layer 140 until first anti-reflective coating layer 130 is opened, in accordance with embodiments. In embodiments, first anti-reflective coating layer 130 may be used as an etch stop film. In embodiments, the contact portion may be secondarily formed using metal contact layer 140. In embodiments, second pattern film 170 may be formed in such a shape as to cover a sidewall of the lower metal line formed using lower metal line layer 120. In embodiments, second pattern film 170 may serve as a passivation film for protecting the lower metal line during a contact portion patterning process.

As illustrated in FIG. 2H, second pattern film 170 may be removed, in accordance with embodiments.

FIG. 2I is a three dimensional depiction of the structure illustrated in FIG. 2H, in accordance with embodiments. Although a contact portion secondarily formed using metal contact layer 140 has been illustrated to have a rectangular cross-sectional shape in FIG. 2I, the secondarily formed contact portion may be formed to have a polygonal or circular cross-section, in accordance with embodiments.

As illustrated in FIG. 2J, insulating film 180 may be formed on/over the semiconductor structure in which the contact portion is secondarily formed using metal contact layer 140. For example, insulating film 180 may be formed by depositing an oxide film by CVD, in accordance with embodiments.

As illustrated in FIG. 2K, planarization process (e.g. chemical mechanical polishing, overall etching using plasma, and/or a similar process) may be performed on insulating film 180 until second anti-reflective coating layer 150 is exposed, in accordance with embodiments. In embodiments that do not include second anti-reflective coating layer 150, a planarization process may be performed until metal contact layer 140 forming a secondarily formed contact portion is exposed.

As illustrated in FIG. 2L, upper metal line layer 190 may be formed on top of insulating film 180, in accordance with embodiments. In embodiments, upper metal line layer 190 may be in contact with the secondarily formed contact portion. In embodiments, third anti-reflective coating layer 200 may be formed on top of upper metal line layer 190. A third pattern film may be formed on top of the third anti-reflective coating layer 200 and may define the shape of the upper metal line, in accordance with embodiments. In embodiments, the third pattern film may be used to pattern third anti-reflective coating layer 200 and upper metal line layer 190 until insulating film 180 is exposed. As a result, the upper metal line may be formed using upper metal line layer 190.

In embodiments, a metal line may be formed by depositing and patterning a metal layer without forming and burying a contact hole, thereby simplifying the formation of the metal line because the process of forming a barrier metal layer inside the contact hole is omitted. In embodiments, various types of problems such as breakage of the barrier metal layer or similar problems may be substantially eliminated, minimized, and/or reduced due to the formation process of the barrier metal layer because forming the barrier metal layer in the contact hole is omitted. In embodiments, the contact may be as long as desired by employing the process of depositing and patterning a metal layer.

In embodiments, it is possible to prevent deterioration (e.g. degradation) of the EM characteristics of an interface between aluminum and a tungsten plug in the related art because a metal line and a plug may be both formed of aluminum and contact resistance may be improved compared to that in a related art tungsten plug structure. In embodiments, the problem of misalignment of a borderless via structure may be prevented because a metal line layer and a contact portion (contact) metal layer may be formed together.

While embodiments have been shown and described, embodiments are not limited thereto. It will be understood by those skilled in the art that various changes and modifications may be made without departing from the scope of the embodiments as defined in the following claims.

What is claimed is:

1. A method for forming a metal line in a semiconductor device, the method comprising:
depositing a metal line layer over a semiconductor substrate;
depositing a metal contact layer over the metal line layer;
patterning the metal line layer to form a lower metal line;
patterning the metal contact layer to form a primarily formed contact portion;
patterning the primarily formed contact portion to form a secondarily formed contact portion;
forming an insulating film over the semiconductor substrate including the secondarily formed contact portion and the lower metal line;
planarizing the insulating film such that the secondarily formed contact portion is exposed; and
forming an upper metal line over the planarized insulating film to be in electrical contact with the secondarily formed contact portion.

2. The method of claim 1, wherein the secondarily formed contact portion, has a polygonal or circular cross-section.

3. The method of claim 1, wherein before patterning the primarily formed contact portion to form a secondarily formed contact portion, forming a passivation film to cover a sidewall of the lower metal line.

4. The method of claim 1, comprising forming an anti-reflective coating layer over at least one of an interface between the metal line layer and the metal contact layer, the top surface of the metal contact layer, and the top surface of the upper metal line.

5. The method of claim 1, wherein the anti-reflective coating layer comprises at least one of a single film of:
titanium (Ti);
titanium nitride (TiN);
a compound of titanium and tungsten (TiW);
tantalum (Ta); and
tantalum nitride (TaN).

6. The method of claim 1, comprising forming a barrier metal film over an interface between the semiconductor substrate and the metal line layer.

7. The method of claim 1, wherein at least one of the metal line layer, the metal contact layer, and the upper metal line are formed of aluminum.

8. The method of claim 1, wherein the metal line layer, the metal contact layer, and the upper metal line are formed of aluminum.

9. An apparatus comprising:
a secondarily formed contact portion, wherein the secondarily formed contact portion is formed by depositing a metal line layer over a semiconductor substrate, depositing a metal contact layer over the metal line layer, patterning the metal line layer for form a lower metal line, patterning the metal contact layer to form a primarily formed contact portion, and patterning the primarily formed contact portion to form the secondarily formed contact portion;
an insulating film formed over the semiconductor substrate including the secondarily formed contact portion and the lower metal line, wherein the insulating film is planarized such that the secondarily formed contact portion is exposed; and
an upper metal line formed over the planarized insulating film in electrical contact with the secondarily formed contact portion.

10. The apparatus of claim 9, wherein the secondarily formed contact portion has a polygonal or circular cross-section.

11. The apparatus of claim 9, wherein before patterning the primarily formed contact portion to form a secondarily formed contact portion, forming a passivation film to cover a sidewall of the lower metal line.

12. The apparatus of claim 9, comprising an anti-reflective coating layer formed over at least one of an interface between the metal line layer and the metal contact layer, the top surface of the metal contact layer, and the top surface of the upper metal line.

13. The apparatus of claim 9, wherein the anti-reflective coating layer comprises at least one of a single film of:
titanium (Ti);
titanium nitride (TiN);
a compound of titanium and tungsten (TiW);
tantalum (Ta); and
tantalum nitride (TaN).

14. The apparatus of claim 9, comprising forming a barrier metal film over an interface between the semiconductor substrate and the metal line layer.

15. The apparatus of claim 9, wherein at least one of the metal line layer, the metal contact layer, and the upper metal line are formed of aluminum.

16. The apparatus of claim 9, wherein the metal line layer, the metal contact layer, and the upper metal line are formed of aluminum.
